(19) United States
(12) Patent Application Publication
(10) Pub. No.: US 2010/0182092 A1
(43) Pub. Date: Jul. 22, 2010

(54) POWER SENSITIVE VARIABLE ATTENUATOR

(76) Inventors: John C. Tremblay, Lancaster, MA (US); Francois Y. Colomb, Westford, MA (US)

Correspondence Address: RAYTHEON COMPANY;c/o DALY, CROWLEY, MOFFORD & DURKEE, LLP, 354A TURNPIKE STREET, SUITE 301A, CANTON, MA, 02021-2714, US

(21) Appl. No.: 12/355,865

(22) Filed: Jan. 19, 2009

(51) Int. Cl. H01P 1/22; H03G 3/00

(52) U.S. Cl. 330/284; 333/81 R

(57) ABSTRACT

A variable attenuator having: an input port; a semiconductor device having a control electrode for controlling carriers flowing between a first electrode and a second electrode, such control electrode being coupled to one of the first and second electrodes, one of the first and second electrodes being coupled to the input port and the other one of the first and second electrodes being coupled to a reference potential to form an active device characterized by such device having a resistivity in the device to the flow of carriers substantially constant when such device is fed through input port with a signal having a relatively small power level and having a resistivity in the device to the flow of carriers which is nonlinear when such device is fed through input port with a signal having a relatively large power level; and an output port coupled to one of the first and second electrodes coupled to the input port. Such a network may be used with a power amplifier to reduce excessive small signal gain and soft compression.

### TECHNICAL FIELD

This invention relates generally to attenuators and more particularly to variable attenuators.

### BACKGROUND AND SUMMARY

As is known in the art, phased array antenna transmit/receive (T/R) modules contain multiple gain stages for amplifying low level RF signals. For a typical transmit state, these gain stages are operated in a nonlinear (saturated) power relationship when the RF input level is within its designed operating range—this reduces transmitted output level sensitivity to temperature, input signal level . . . etc. However, a linear (one-for-one) power relationship exists when the RF input level is at extremely low levels (quiescent operating point or between pulsed RF waveforms). Hence, the gain of the 2-port transmit network is greater in the backed off (linear) mode than the operational (nonlinear) mode. Typically, the gain difference may average 3 dB or more per gain stage (application specific)—for example; a typical transmit chain having 5 gain stages resulting in more than 15 dB relative gain between the linear and nonlinear operating states.

A similar case for T/R modules utilizing GaN HEMT RF amplifiers exists; however, the relative transmit gain between linear and nonlinear operating conditions may be as much as 30 dB due to a soft compression transfer characteristic related to gate-connected field plates which magnify a change in the complex input impedance vs. RF drive level. This input impedance shift changes the power transfer coefficient between the impedance matching networks and the gain stage transistor which results in excessive gain for the low RF level condition as shown in FIG. 1.

In accordance with the present invention, a power sensitive variable attenuator is provided having: an input port; a semiconductor device having a control electrode for controlling carriers flowing between a first electrode and a second electrode, such control electrode being coupled to one of the first and second electrodes, one of the first and second electrodes being coupled to the input port and the other one of the first and second electrodes being coupled to a reference potential to form an active device characterized by such device operating in: 1) a linear region of the device when such device is fed through input port with a signal having a relatively small power level; 2) a non-linear region of the device when such device is fed through input port with a signal having a medium power level; and 3) a saturated region of the device when such device is fed through the input port with a signal having a relatively large power; and an output port coupled to the one of the first and second electrodes coupled to the input port.

In accordance with one embodiment, a variable attenuator is provided having: an input port; a semiconductor device having a control electrode for controlling carriers flowing between a first electrode and a second electrode, such control electrode being coupled to one of the first and second electrodes, one of the first and second electrodes being coupled to the input port and the other one of the first and second electrodes being coupled to a reference potential to form an active device characterized by such device having a resistivity in the device to the flow of carriers substantially constant when such device is fed through input port with a signal having a relatively small power level and having a resistivity in the device to the flow of carriers which is nonlinear and increases in value when such device is fed through input port with a signal having a relatively large power level; and an output port coupled to the one of the first and second electrodes coupled to the input port.

In one embodiment, the device is a transistor.

In one embodiment, the input port is coupled to the device through a resistor.

In one embodiment, the device is coupled to the output port through a second resistor.

In one embodiment, the device is a transistor arranged as a current source.

In one embodiment, the attenuator is arranged as a T-type network.

In one embodiment a pair of the devices is included and the attenuator is arranged as a Pi-type network.

In one embodiment, an amplifier system is provided having a gain vs. input power characteristic wherein the gain of the amplifier is substantially constant when fed an input signal having a relatively low input power level over a first, relatively low range of power levels and wherein such gain progressively decreases as the input signal has a progressively increasing power level over a second, relatively high range of power levels. The amplifier system includes a power sensitive variable attenuator having: an input port fed by the input signal; and an output port. The amplifier system includes: an amplifier having an input fed by the output port of the power sensitive variable attenuator. The amplifier has a gain vs. input power characteristic wherein the gain of the amplifier progressively decreases as a signal fed to the input of the amplifier progressively increases in power through the first, relatively low range of power levels and then through the second, relatively high range of power levels. The power sensitive variable attenuator comprises: a semiconductor device having a control electrode for controlling carriers flowing between a first electrode and a second electrode, such control electrode being coupled to one of the first and second electrodes, one of the first and second electrodes being coupled to the input port and the other one of the first and second electrodes being coupled to a reference potential to form an active device characterized by such device operating in a linear region of the device when such device is fed through the input port with a signal having a power level in the first, relatively low range of power levels and operating in a saturated region of the device when such device is fed through the input port with a signal having a power level in the second, relatively high range of power levels. The output port of the power sensitive variable attenuator is coupled to the input port of the amplifier and wherein the output port is coupled to one of the first and second electrodes.

The inventors have developed a simple solution for this problem. An RF power level drive dependent attenuating element (i.e., a power sensitive variable attenuator) is coupled to the input of the amplifier. Thus, the RF signal to be amplified is first fed to the power sensitive variable attenuator prior to the GaN HEMT RF amplifier. The power sensitive variable attenuator negates the excessive gain due to soft compression in the GaN HEMT RF amplifier at relatively low input power, thereby resulting in a power sensitive variable attenuator- GaN HEMT RF amplifier combination with constant gain over a range of low to medium input powers, and a sharp transition to the saturated power relationship when the RF input level increases to relatively high input power levels.

The power sensitive variable attenuator may be formed by a ‘T-type’, Pi-type’, or other fixed attenuator design with one simple change—some fixed value resistors are replaced with a variable resistance being a FET configured as a current source. When the gate-source terminals of a depletion-mode FET are connected (Vgs=0V) the drain-source resistivity is nearly constant at low RF levels and behaves linearly. The low RF level resistivity can be altered by adjusting FET periphery to provide a well-matched fixed attenuation value in the linear operating region with a widely variable initial attenuation value. As the RF level increases, the channel current of the FET approaches saturation (IDSS) and a transition to nonlinear behavior occurs. This results in an increase in resistivity relative to input RF level and the desired power dependent attenuation.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a diagram of gain as a function of input power to an amplifier exhibiting soft compression according to the PRIOR ART;

FIG. 2 is a block diagram of an amplifier system according to the invention;

FIGS. 3A, 3B and 3C are diagrams of gain versus input power showing the attenuation of various elements of the amplifying system of FIG. 2 according to the invention;

FIGS. 4A, 4B and 4C are diagrams of output power vs. input power showing the attenuation of various elements of the amplifying system of FIG. 2 according to the invention;

FIGS. 5A and 5B are equivalent circuit and schematic diagrams, respectively, of a power sensitive variable attenuator according to the invention; and

FIGS. 6A and 6B are equivalent circuit and schematic diagrams, respectively, of a power sensitive variable attenuator according to another embodiment of the invention.

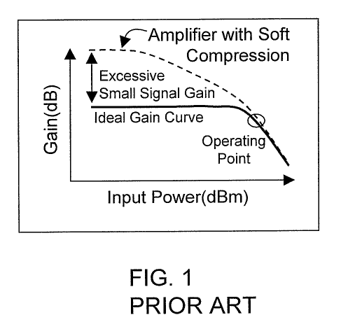

Like reference symbols in the various drawings indicate like elements.

### DETAILED DESCRIPTION

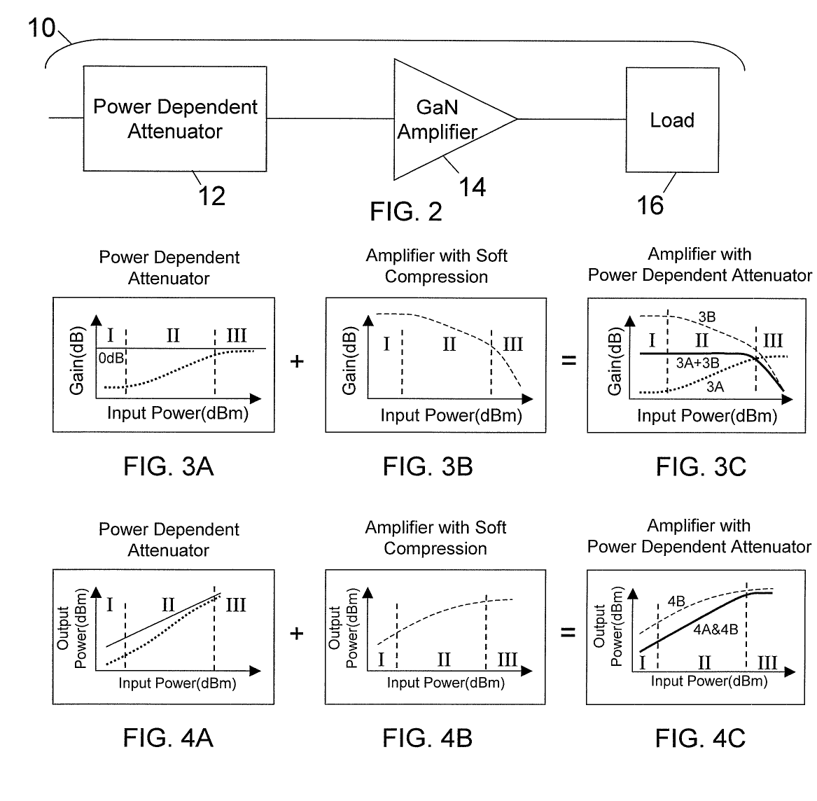

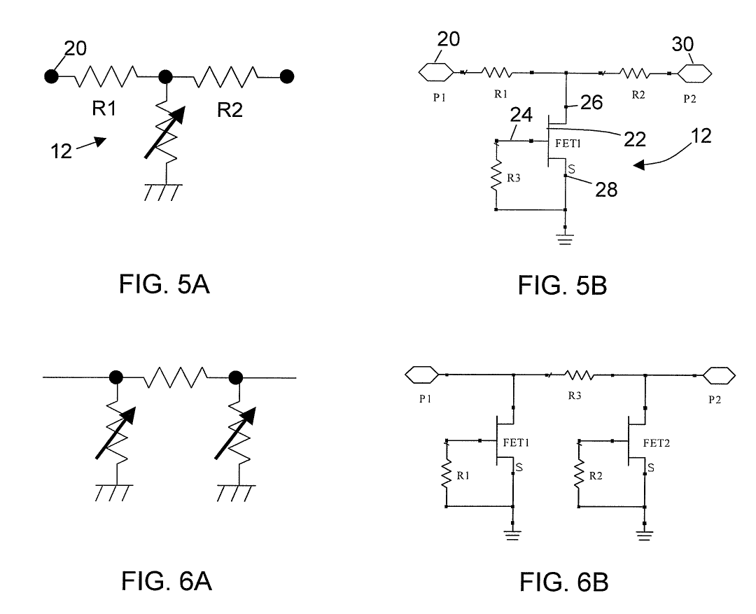

Referring now to FIG. 2, an RF amplifier system 10 is shown. The system 10 includes a power sensitive variable attenuator 12 (FIG. 5) fed by an RF input signal, an amplifier, here a GaN amplifier 14, fed by the attenuator 12, and a load 16 fed by the amplifier 14. As shown in FIG. 3A, the attenuation of the attenuator has three separate regimes, labeled I, II, and III. In region I corresponding to low input power level, the attenuation is constant. In region II, the attenuation decreases with input power level of the input signal fed to the attenuator 12. In region III, the attenuation of the attenuator approaches unity gain at very large input power levels. It is noted that the attenuation is indicated in decibels (dB). The gain of the amplifier 14, here also indicated in dB, is constant for low input power levels (region I), decreases gradually with increasing medium input power levels as a result of soft-compression (region II), and decreases linearly with input power for high power levels in saturation (region III), as shown in FIG. 3B. Thus, the overall relationship, again in dB, between the input signal power level fed to the attenuator 12 and the output power of the amplifier 14, again in dB is constant gain over the range of low to medium input signal power levels and linearly decreasing gain generating the desired amplifier compression levels above the desired threshold between constant gain and saturated power amplifier operation, as shown in FIG. 3C. Note, that in FIG. 3C, the curves include the attenuator 12 (3A), amplifier 14 (3B) and the resultant behavior identified as 3A+3B. Corresponding output power vs. input power relationships for variable attenuator 12, amplifier 14, and amplifier system 10 are shown in FIG. 4A, 4B, and 4C respectively.

Referring now to FIG. 5B, the power sensitive variable attenuator 12 is shown (along with its equivalent circuit FIG. 5A), to include an input port 20; a semiconductor device 22 (FET1), here a Field-Effect Transistor (FET), having a control, here gate, electrode 24 for controlling carriers flowing between a first, here drain, electrode 26 and a second, here source, electrode 28, such control electrode 24 being coupled to one of the first and second electrodes, here to the source electrode 28 through a resistor R3. Also, one of the first and second electrodes, here the drain electrode 26, is coupled to the input port 20 through a resistor R1 and the other one of the first and second electrodes, here the source electrode 28, is coupled to a reference potential, here ground potential, to form an active device 22 characterized by such device 22 having a resistivity in the device 22 to the flow of carriers substantially constant when such device 22 is fed through input port 20 with a signal having a relatively small power level and having a resistivity in the device 22 to the flow of carriers being nonlinear and increasing in value when such device 22 is fed through input port 20 with a signal having medium to high power levels; and an output port 30 coupled through a resistor R2 to the one of the first and second electrodes coupled through a resistor R1 to the input port 20.

As noted above, the input port 20 is coupled to the device 22 through a resistor, R1 and the device 22 is coupled to the output port 30 through a second resistor, R2. The device 22 is a transistor arranged as a current source. The resulting attenuator 12 is a T-type network with the active device 22 being disposed in a shunt path of such network.

It is noted that attenuation reduces as input power increases because the resistance of the shunt arm having the transistor 22 increases with input power. At low input power the resistance is relatively low, and careful selection of resistor values R1 and R2, as well as FET1 periphery, forms a well-matched circuit (compared to the port 20 impedance); the shunt arm thereby introduces additional insertion loss. At high input power the non-linear behavior of the transistor 22 results in relatively high impedance effectively reducing the topology to the series resistors R1 and R2 placed in the series arm. In the range of medium input powers, i.e. between low and high input power levels, the resistance increases gradually at a rate which can be adjusted by design to compensate the rate of soft compression of amplifier 14. The input port 20 impedance is the reference impedance in which the circuit is embedded, usually 50 ohms.

More particularly, there is a reference impedance, in this case 50 ohms and there are input and output impedances. The input impedance is the impedance of the attenuator 12 when the output is terminated with a load equal to the reference impedance. Likewise, the output impedance is the impedance looking into the output of the network when the input is terminated with a load equal to the reference impedance. Now, the insertion loss that we are so interested in controlling can occur as a result of: 1) dissipation in the network; 2) reflection at the input due to impedance mismatch between the input impedance and the reference impedance; 3) a combination of dissipative and reflective losses. Proper design using dissipation inside the network allows one to maintain input and output impedances close to the reference, which is extremely desirable—reflections can cause all sorts of problems in a module including gain ripple and oscillations. The Tee networks shown in FIG. 5A and FIG. 5B and the Pi networks shown in FIG.6A and FIG. 6B, described herein, are just like that, i.e., they have the desirable property of maintaining good input and output impedances over the range of expected RF input levels. The quality of the match varies somewhat with input power but is usually optimized for the amplifier 14 high-gain conditions (low input power) by design. In the case of the Pi network, good input (and output) match is accomplished by proper balance between the impedance of the shunt arms and the resistor in the series arm. The reference impedance is a given. Unless otherwise specified the common assumption in circuit design is 50 ohms.

In the Pi network of FIG. 6A and 6B, attenuation reduces as input power increases because the resistance of the shunt arms containing transistors increases with input power. At low input power the resistance is relatively low compared to the port impedances; the shunt arms thereby introduce insertion loss. At high input power the non-linear behavior of the transistors results in a relatively high impedance effectively reducing the topology to the series resistor placed between the two shunt arms.

It is noted that while here the device is a FET, MIS FETs and bipolar transistors may also be used. More particularly, any three terminal device with the control electrode being connected directly or indirectly to either of the other two electrodes forms an active load characterized by a linear region under small signal and a non-linear region under medium- and large signal. The different transistors will have different conduction characteristic in the first and third quadrant. The design has to be tailored to each type of transistor but in essence they should all be applicable.

The gain of any amplifier will start compressing when the voltage or current in any of the amplifier stages reaches its maximum capacity. This is sometimes referred to as ‘hitting the rails’. Beyond that point, the amplifier can no longer amplify a signal linearly, i.e. maintain a constant gain. In practice, this is a gradual process but many amplifiers can be designed to have near ideal gain versus input power. An ideal response would be constant gain and a short transition region into hard compression where output power saturates at a ceiling value. In hard compression, gain will be inversely proportional to input power since output power is constant and input power keeps increasing. The invention addresses the level of gain at low input powers. The invention prevents excessive system gain at low input power by introducing well-matched lossy networks. Without a circuit like that of the invention or some other means to offset small signal gain, there is a consistent tendency for certain transistor technologies such as GaN with field-plates to produce high small signal gain causing design difficulties. Although small signal gain is desirable in certain kinds of amplifiers such as driver amplifiers and low noise amplifiers, for a power amplifier the critical gain that matters is in the compressed region, at or near peak efficiency. Excessive gain at low input power can cause all sorts of problems including stability issues and free running oscillations, i.e. oscillations even without an input RF signal. We have in fact had such problems with several generations of GaN amplifiers that oscillated when assembled into modules producing higher system gain levels than previous amplifier technologies. The invention reduces small signal gain effectively, thereby reducing the build up of excessive gain in a module as amplifiers are cascaded in a chain, and thereby greatly reducing the risk of amplifier instabilities. The attenuator may be fabricated using microstrip or coplanar waveguide transmission lines as a stand-alone network or incorporated into the amplifier's outline when technologies are matched. The amplifier outline can be a single Microwave Monolithic Integrated Circuit (MMIC) or a network of separate transistors and matching networks known in the art as a hybrid amplifier.

A number of embodiments of the invention have been described. Nevertheless, it will be understood that various modifications may be made without departing from the spirit and scope of the invention. For example with an enhancement mode device implementation, an external DC bias control may be added for the control electrode even though one of the assets of this invention is that it does not require external bias or any other connections besides input RF, output RF and ground. Further, the variable power sensitive attenuator may be used to create more elaborate networks such as a Balanced TEE or Balanced Pi network. Accordingly, other embodiments are within the scope of the following claims.

1. A power sensitive variable attenuator, comprising:
an input port;
a semiconductor device having a control electrode for controlling carriers flowing between a first electrode and a second electrode, such control electrode being coupled to one of the first and second electrodes, one of the first and second electrodes being coupled to the input port and the other one of the first and second electrodes being coupled to a reference potential to form an active device wherein the device operates in a linear region of the device when such device is fed through the input port with a signal having a first power level and operates in a saturated region of the device when such device is fed through the input port with a signal having a second power level larger than the first power level; and
an output port coupled to the one of the first and second electrodes coupled to the input port.

2. The power sensitive variable attenuator recited in claim 1 wherein the device is a transistor.

3. The power sensitive variable attenuator recited in claim 2 wherein the input port is coupled to the device through a resistor.

4. The power sensitive variable attenuator recited in claim 3 wherein the device is coupled to the output port through a second resistor.

5. The power sensitive variable attenuator recited in claim 1 wherein the device is a transistor arranged as a current source.

6. A power sensitive variable attenuator, comprising:
an input port;
a semiconductor device having a control electrode for controlling carriers flowing between a first electrode and a second electrode, such control electrode being coupled to one of the first and second electrodes, one of the first and second electrodes being coupled to the input port and the other one of the first and second electrodes being coupled to a reference potential to form an active device wherein the device has a resistivity to the flow of the carriers substantially constant when such device is fed through the input port with a signal having a first power level and has a non-linear resistivity to the flow of carriers when such device is fed through the input port with a signal having a second power level, the second power level being larger than the first power level; and
an output port coupled to the one of the first and second electrodes coupled to the input port.

7. The power sensitive variable attenuator recited in claim 6 wherein the device is a transistor.

8. The power sensitive variable attenuator recited in claim 7 wherein the input port is coupled to the device through a resistor.

9. The power sensitive variable attenuator recited in claim 8 wherein the device is coupled to the output port through a second resistor.

10. The power sensitive variable attenuator recited in claim 6 wherein the device is a transistor arranged as a current source.

11. A power sensitive variable attenuator comprising:
an input port;
a semiconductor device having a control electrode for controlling carriers flowing between a first electrode and a second electrode, such control electrode being coupled to one of the first and second electrodes, one of the first and second electrodes being coupled to the input port and the other one of the first and second electrodes being coupled to a reference potential to form an active device wherein such device operates in: 1) a linear region of the device when such device is fed through the input port with a signal having a first power level; 2) a non-linear region of the device when such device is fed through the input port with a signal having a second power level; and 3) a saturated region of the device when such device is fed through the input port with a signal having a third power level, and wherein the second power level is larger than the first power level and wherein the third power level is larger than the second power level; and
an output port coupled to the one of the first and second electrodes coupled to the input port.

12. A power sensitive variable attenuator comprising:
an input port;
a semiconductor device having a control electrode for controlling carriers flowing between a first electrode and a second electrode, such control electrode being coupled to one of the first and second electrodes, one of the first and second electrodes being coupled to the input port and the other one of the first and second electrodes being coupled to a reference potential to form an active device, wherein such device has a resistivity to the flow of carriers substantially constant when such device is fed through the input port with a signal having a first power level and has a resistivity to the flow of carriers which is nonlinear and which increases in resistivity when such device is fed through the input port with a signal having a second power level, and wherein the second power is larger than the first power level; and
an output port coupled to the one of the first and second electrodes coupled to the input port.

13. An amplifier system, comprising:
a power sensitive variable attenuator having:
an input port fed by an input signal; and
an output port;
an amplifier having an input fed by the output port of the power sensitive variable attenuator;
wherein the amplifier has a gain vs. input power characteristic wherein the gain of the amplifier progressively decreases as a signal fed to the input of the amplifier progressively increases in power through a first range of power levels and then through a second range of power levels higher than the first range of power levels;
wherein the power sensitive variable attenuator comprises:
a semiconductor device having a control electrode for controlling carriers flowing between a first electrode and a second electrode, such control electrode being coupled to one of the first and second electrodes, one of the first and second electrodes being coupled to the input port and the other one of the first and second electrodes being coupled to a reference potential to form an active device, wherein such device operates in a linear region of the device when such device is fed through the input port with a signal having a power level in the first range of power levels and operates in a saturated region of the device when such device is fed through the input port with a signal having a power level in the second range of power levels; and
wherein the output port is coupled to the one of the first and second electrodes.
